(19) United States
(12) Patent Application Publication
(10) Pub. No.: US 2021/0395024 A1
(43) Pub. Date: Dec. 23, 2021

(54) WAFER COATING DEVICE AND FACE-DOWN TYPE WAFER CARRYING ASSEMBLY THEREOF

(71) Applicant: ASTI GLOBAL INC., TAIWAN, Taichung City (TW)

(72) Inventor: CHIEN-SHOU LIAO, New Taipei City (TW)

(21) Appl. No.: 17/353,771

(22) Filed: Jun. 21, 2021

Related U.S. Application Data
(60) Provisional application No. 63/042,040, filed on Jun. 22, 2020.

(51) Int. Cl. B65G 47/92; H01L 21/677; H01F 7/02; C23C 16/52; C23C 16/458

(52) U.S. Cl. CPC B65G 47/92; H01L 21/67733; C23C 16/4583; C23C 16/52; H01F 7/0257

(57) ABSTRACT

A wafer coating device and a face-down type wafer carrying assembly thereof are provided. The face-down type wafer carrying assembly includes a magnetic force generating module, a temperature control module, and a magnetizable module. The temperature control module is adjacent to the magnetic force generating module. The magnetizable module is disposed on the temperature control module. The magnetizable module includes a high-temperature magnetizable metal plate disposed on the temperature control module. When at least one wafer is temporarily adhered to the adhesive bottom surface of the high-temperature adhesive layer, a prepared surface of the at least one wafer can face downwardly by adhering of the adhesive bottom surface of the high-temperature adhesive layer, so that the face-down type wafer carrying assembly can be applied to solve the problem that the prepared surface of the wafer would be dirtied by falling particles due to gravity.

### CROSS-REFERENCE TO RELATED PATENT APPLICATION

This application claims priority to the U.S. Provisional Patent Application Ser. No. 63/042,040 filed on Jun. 22, 2020, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a coating device and a carrying assembly thereof, and more particularly to a wafer coating device and a face-down type wafer carrying assembly thereof.

### BACKGROUND OF THE DISCLOSURE

In the related art, a face-up type deposition design is employed generally in a metal-organic chemical vapor deposition (MOCVD) equipment for coating a metal organic material on a wafer under a high working temperature above 900° C. However, the falling particles will inevitably contaminate a surface of the wafer for this kind of the face-up type deposition design.

### SUMMARY OF THE DISCLOSURE

In response to the above-referenced technical inadequacy, the present disclosure provides a wafer coating device and a face-down type wafer carrying assembly thereof.

In one aspect, the present disclosure provides a face-down type wafer carrying assembly including a magnetic force generating module, a temperature control module, and a magnetizable module. The temperature control module is adjacent to the magnetic force generating module. The magnetizable module is disposed on the temperature control module. The magnetizable module includes a high-temperature magnetizable metal plate disposed on the temperature control module.

In certain embodiments, the magnetic force generating module includes a permanent magnetic structure, and a cooling structure contacting the permanent magnetic structure.

In certain embodiments, the magnetic force generating module includes an electromagnetic structure, a power supply electrically connected to the electromagnetic structure, and a cooling structure contacting the electromagnetic structure.

In certain embodiments, the temperature control module includes a plate heater and a graphite plate disposed on the plate heater.

In certain embodiments, the high-temperature magnetizable metal plate is a cobalt-rich alloy plate or a pure cobalt material plate.

In certain embodiments, the high-temperature magnetizable metal plate has a thickness ranging from 30 μm to 30 mm, the high-temperature magnetizable metal plate has an operating temperature less than 1200° C., and the high-temperature magnetizable metal plate is made of a material that is selected from the group consisting of a cobalt (Co), an aluminium (Al), a nickel (Ni), a copper (Cu), a titanium (Ti) and an iron (Fe).

In certain embodiments, based on 100 wt % of a material for manufacturing the high-temperature magnetizable metal plate, the material includes from 40 wt % to less than 100 wt % of a cobalt (Co), 3 to 7 wt % of an aluminium (Al), 8 to 12 wt % of a nickel (Ni), less than 6 wt % of a copper (Cu), less than 1 wt % of a titanium (Ti), and a remaining percentage by weight of an iron (Fe).

In certain embodiments, the magnetizable module includes at least one high-temperature adhesive layer disposed on the high-temperature magnetizable metal plate, and the at least one high-temperature adhesive layer faces downwardly; wherein the at least one high-temperature adhesive layer has an operating temperature less than 2000° C., the at least one high-temperature adhesive layer has an adhesive bottom surface facing downwardly, and at least one wafer is temporarily adhered to the adhesive bottom surface of the at least one high-temperature adhesive layer.

In another aspect, the present disclosure provides a wafer coating device using a face-down type wafer carrying assembly, and the face-down type wafer carrying assembly includes a magnetic force generating module, a temperature control module, and a magnetizable module. The temperature control module is adjacent to the magnetic force generating module. The magnetizable module is disposed on the temperature control module. The magnetizable module includes a high-temperature magnetizable metal plate disposed on the temperature control module.

In yet another aspect, the present disclosure provides a wafer coating device including a top chamber structure and a bottom chamber structure mated with the top chamber structure. The wafer coating device uses a face-down type wafer carrying assembly that is disposed on the top chamber structure, and the face-down type wafer carrying assembly includes a magnetic force generating module, a temperature control module, and a magnetizable module. The temperature control module is adjacent to the magnetic force generating module. The magnetizable module is disposed on the temperature control module. The magnetizable module includes a high-temperature magnetizable metal plate disposed on the temperature control module.

Therefore, by virtue of “the temperature control module being adjacent to the magnetic force generating module”, “the magnetizable module being disposed on the temperature control module” and “the magnetizable module including a high-temperature magnetizable metal plate disposed on the temperature control module”, when at least one wafer is temporarily adhered to the adhesive bottom surface of the high-temperature adhesive layer, a prepared surface of the at least one wafer can face downwardly by adhering of the adhesive bottom surface of the high-temperature adhesive layer, so that the face-down type wafer carrying assembly can be applied to solve the problem of “the prepared surface of the wafer would be dirtied (or contaminated) by falling particles due to gravity”.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a face-down type wafer carrying assembly using a high-temperature adhesive layer according to a first embodiment of the present disclosure;

FIG. 2 is a schematic side view of the face-down type wafer carrying assembly using two high-temperature adhesive layers according to the first embodiment of the present disclosure;

FIG. 3 is a schematic side view of a wafer coating device including a top chamber structure and a bottom chamber structure separated from each other according to the first embodiment of the present disclosure;

FIG. 4 is a schematic side view of the wafer coating device including the top chamber structure and the bottom chamber structure matching with each other according to the first embodiment of the present disclosure;

FIG. 5 is a schematic enlarged view of part V of FIG. 4;

FIG. 6 is a schematic side view of a face-down type wafer carrying assembly using a high-temperature adhesive layer according to a second embodiment of the present disclosure; and

FIG. 7 is a schematic side view of the face-down type wafer carrying assembly using two high-temperature adhesive layers according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

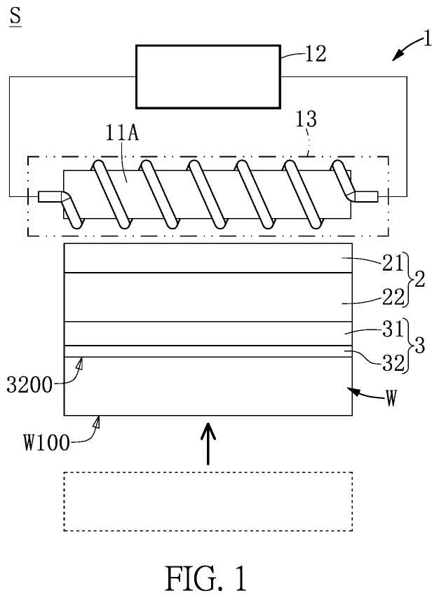

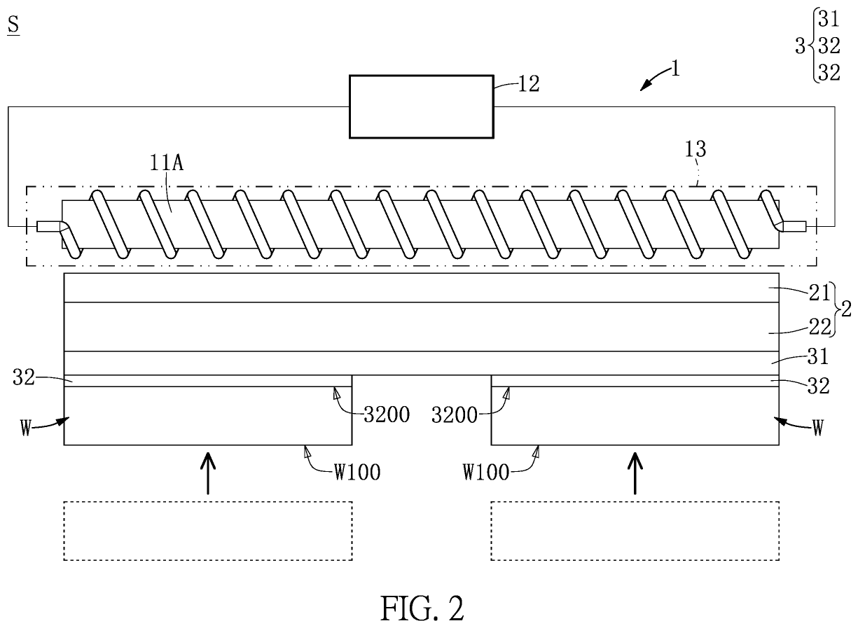

Referring to FIG. 1 and FIG. 2, a first embodiment of the present disclosure provides a face-down type wafer carrying assembly S including a magnetic force generating module 1, a temperature control module 2, and a magnetizable module 3. More particularly, the temperature control module 2 is adjacent to the magnetic force generating module 1, and the magnetizable module 3 is disposed on the temperature control module 2. In addition, the magnetizable module 3 includes a high-temperature magnetizable metal plate 31 and at least one high-temperature adhesive layer 32. The high-temperature magnetizable metal plate 31 is disposed on the temperature control module 2, and the at least one high-temperature adhesive layer 32 is disposed on the high-temperature magnetizable metal plate 31.

For example, as shown in FIG. 1 or FIG. 2, the magnetic force generating module 1 includes an electromagnetic structure 11A, a power supply 12 electrically connected to the electromagnetic structure 11A, and a cooling structure 13 contacting the electromagnetic structure 11A. More particularly, the electromagnetic structure 11A includes a magnetic core and a coil disposed around the magnetic core. When predetermined electric power provided by the power supply 12 is transmitted to the electromagnetic structure 11A through the coil, the electric power can be converted into magnetic power having a predetermined strength by the electromagnetic structure 11A. In addition, when a temperature generated by the electromagnetic structure 11A is too high, the electromagnetic structure 11A can be cooled by the cooling structure 13. However, the aforementioned description is merely an example and is not meant to limit the scope of the present disclosure.

For example, as shown in FIG. 1 or FIG. 2, the temperature control module 2 includes a plate heater 21 (or a heating plate) and a graphite plate 22 disposed on the plate heater 21. More particularly, the plate heater 21 cannot directly contact the magnetic force generating module 1 (or the plate heater 21 can directly contact the magnetic force generating module 1), and the plate heater 21 can be a temperature control device for controlling a temperature generated by the plate heater 21. In addition, the graphite plate 22 can directly contact the plate heater 21, and the plate heater 21 can be replaced with any type of heat guide plate having a good heat-transferring capability (such as a metal heat-guiding plate or a nonmetallic heat-guiding plate). However, the aforementioned description is merely an example and is not meant to limit the scope of the present disclosure.

For example, as shown in FIG. 1 or FIG. 2, the high-temperature magnetizable metal plate 31 has a thickness ranging from 30 μm to 30 mm (such as any arbitrary positive integer ranging from 30 μm to 3000 μm), and the high-temperature magnetizable metal plate 31 has an operating temperature (or working temperature) less than 1200° C. (such as any arbitrary positive integer below 1200° C.). More particularly, the high-temperature magnetizable metal plate 31 can be a cobalt-rich alloy plate or a pure cobalt material plate, or the high-temperature magnetizable metal plate 31 can be made of a material that can be selected from the group consisting of a cobalt (Co), an aluminium (Al), a nickel (Ni), a copper (Cu), a titanium (Ti) and an iron (Fe). In addition, when the high-temperature magnetizable metal material of the high-temperature magnetizable metal plate 31 is selected from the group consisting of Co, Al, Ni, Cu, Ti and Fe, based on 100 wt % (weight percent) of the high-temperature magnetizable metal material for manufacturing the high-temperature magnetizable metal plate 31, the material can include from 40 wt % to less than 100 wt % (such as any arbitrary positive integer ranging from 40 wt % to less than 100 wt %) of Co, 3 to 7 wt % (such as any arbitrary positive integer ranging from 3 to 7 wt %) of Al, 8 to 12 wt % (such as any arbitrary positive integer ranging from 8 to 12 wt %) of Ni, equal to or less than 6 wt % (such as any arbitrary positive integer below 6 wt %) of Cu, equal to or less than 1 wt % (such as any arbitrary positive integer below 1 wt %) of Ti, and a remaining percentage by weight of Fe. It should be noted that based on 100 wt % of the high-temperature magnetizable metal material for manufacturing the high-temperature magnetizable metal plate 31, when the percentages by weight of Al, Ni, Cu, Ti and Fe are 3%, 8%, 6%, 1% and 2%, respectively, the weight percent of Co can be 80%. However, the aforementioned description is merely an example and is not meant to limit the scope of the present disclosure.

For example, as shown in FIG. 1 or FIG. 2, the magnetizable module 3 can include a high-temperature adhesive layer 32 (as shown in FIG. 1) or more than one high-temperature adhesive layers 32 (such as two high-temperature adhesive layers 32 as shown in FIG. 2). More particularly, the high-temperature adhesive layer 32 has an operating temperature less than 2000° C. (such as arbitrary positive integer below 2000° C., the high-temperature adhesive layer 32 still has excellent adhesive property), and the high-temperature adhesive layer 32 has an adhesive bottom surface 3200 facing downwardly for temporarily sticking at least one wafer W thereto. That is to say, as shown in FIG. 1, when at least one wafer W (such as a sapphire wafer) can be temporarily adhered to the adhesive bottom surface 3200 of the high-temperature adhesive layer 32, a prepared surface W100 (preparing for being deposited or coated) of the at least one wafer W faces downwardly. As shown in FIG. 2, when two (or more than two) wafers W can be temporarily and respectively adhered to two (or more than two) adhesive bottom surfaces 3200 of the high-temperature adhesive layer 32, a prepared surface W100 of each of the two wafers W faces downwardly. Therefore, the prepared surface W100 of the wafer W can face downwardly by adhering to the high-temperature adhesive layer 32 that is disposed under the face-down type wafer carrying assembly S, so that the face-down type wafer carrying assembly S can be applied to solve the problem of “the prepared surface W100 of the wafer W would be dirtied (or contaminated) by falling particles due to gravity”. However, the aforementioned description is merely an example and is not meant to limit the scope of the present disclosure.

More particularly, referring to FIG. 2 to FIG. 5, the first embodiment of the present disclosure further includes a wafer coating device D (or a wafer depositing device) using a face-down type wafer carrying assembly S of the first embodiment. The face-down type wafer carrying assembly S includes a magnetic force generating module 1, a temperature control module 2, and a magnetizable module 3, and the magnetizable module 3 includes two high-temperature adhesive layers 32.

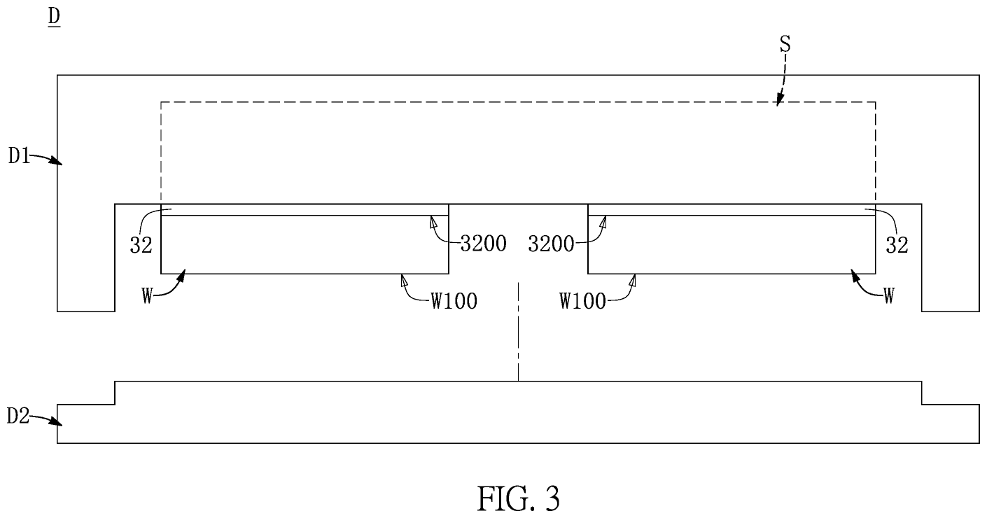

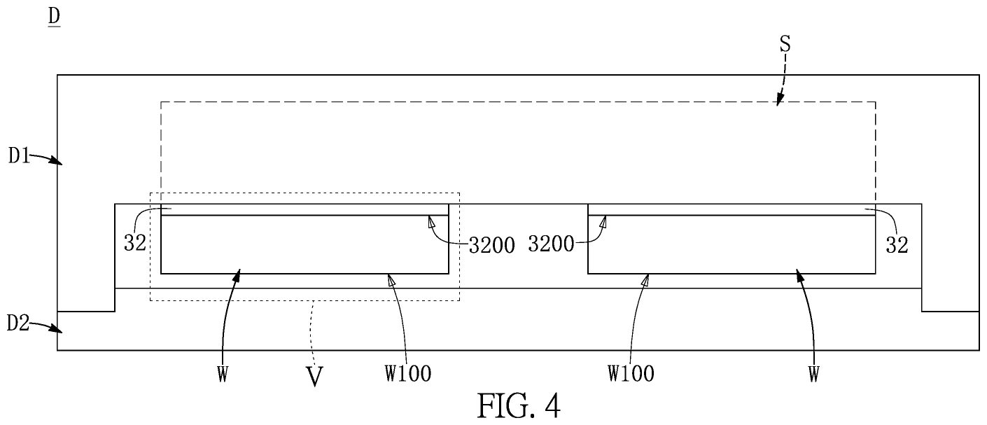

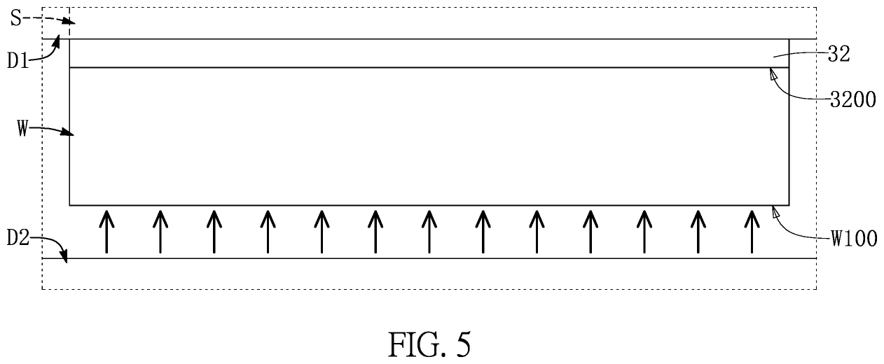

For example, referring to FIG. 3 and FIG. 4, the wafer coating device D includes a top chamber structure D1 and a bottom chamber structure D2 mated with the top chamber structure D1, and the face-down type wafer carrying assembly S is disposed on the top chamber structure D1. In addition, each of two the high-temperature adhesive layers 32 has an adhesive bottom surface 3200 facing downwardly for temporarily sticking at least one wafer W thereto. More particularly, referring to FIG. 4 and FIG. 5, the wafer coating device D can be a metal-organic chemical vapor deposition (MOCVD) device. When the top chamber structure D1 and the bottom chamber structure D2 match with each other, a predetermined depositing material provided by the wafer coating device D can be upwardly deposited (as shown by upward arrows along an upward coating direction in FIG. 5) on the prepared surface W100 of the wafer W, so that the face-down type wafer carrying assembly S can be applied to solve the problem of “the prepared surface W100 of the wafer W would be dirtied (or contaminated) by falling particles due to gravity”. However, the aforementioned description is merely an example and is not meant to limit the scope of the present disclosure.

### Second Embodiment

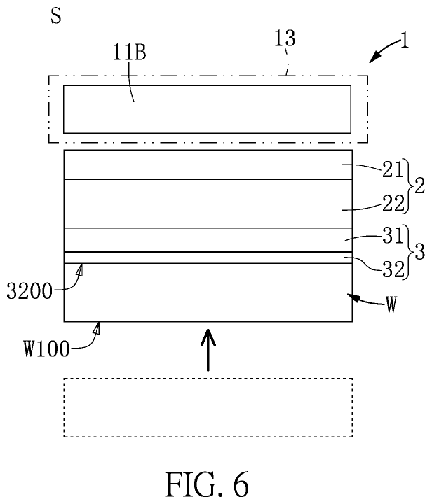

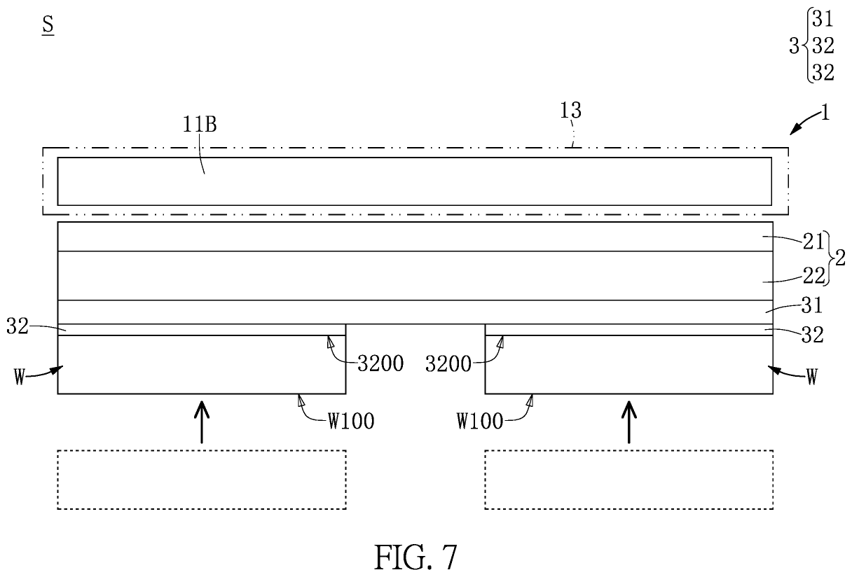

Referring to FIG. 6 and FIG. 7, a second embodiment of the present disclosure provides a face-down type wafer carrying assembly S. Comparing FIG. 6 with FIG. 1, and comparing FIG. 7 with FIG. 2, the difference between the second embodiment and the first embodiment is as follows: in the second embodiment, the magnetic force generating module 1 includes a permanent magnetic structure 11B, and a cooling structure 13 contacting the permanent magnetic structure 11B. That is to say, the permanent magnetic structure 11B can generate magnetic power without a power supply, so that the face-down type wafer carrying assembly S of the second embodiment can be worked without the power supply.

More particularly, the second embodiment of the present disclosure further includes a wafer coating device (not shown) using a face-down type wafer carrying assembly S of the second embodiment. The face-down type wafer carrying assembly S includes a magnetic force generating module 1, a temperature control module 2, and a magnetizable module 3.

### Beneficial Effects of the Embodiments

In conclusion, by virtue of “the temperature control module 2 being adjacent to the magnetic force generating module 1”, “the magnetizable module 3 being disposed on the temperature control module 2” and “the magnetizable module 3 including a high-temperature magnetizable metal plate 31 disposed on the temperature control module 2”, when at least one wafer W is temporarily adhered to the adhesive bottom surface 3200 of the high-temperature adhesive layer 32, a prepared surface W100 of the at least one wafer W can face downwardly by adhering of the adhesive bottom surface 3200 of the high-temperature adhesive layer 32, so that the face-down type wafer carrying assembly S can be applied to solve the problem of “the prepared surface W100 of the wafer W would be dirtied (or contaminated) by falling particles due to gravity”.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A face-down type wafer carrying assembly, comprising:
a magnetic force generating module;
a temperature control module adjacent to the magnetic force generating module; and
a magnetizable module disposed on the temperature control module;
wherein the magnetizable module includes a high-temperature magnetizable metal plate disposed on the temperature control module.

2. The face-down type wafer carrying assembly according to claim 1, wherein the magnetic force generating module includes a permanent magnetic structure, and a cooling structure contacting the permanent magnetic structure.

3. The face-down type wafer carrying assembly according to claim 1, wherein the magnetic force generating module includes an electromagnetic structure, a power supply electrically connected to the electromagnetic structure, and a cooling structure contacting the electromagnetic structure.

4. The face-down type wafer carrying assembly according to claim 1, wherein the temperature control module includes a plate heater and a graphite plate disposed on the plate heater.

5. The face-down type wafer carrying assembly according to claim 1, wherein the high-temperature magnetizable metal plate is a cobalt-rich alloy plate or a pure cobalt material plate.

6. The face-down type wafer carrying assembly according to claim 1, wherein the high-temperature magnetizable metal plate has a thickness ranging from 30 μm to 30 mm, the high-temperature magnetizable metal plate has an operating temperature less than 1200° C., and the high-temperature magnetizable metal plate is made of a material that is selected from the group consisting of a cobalt (Co), an aluminium (Al), a nickel (Ni), a copper (Cu), a titanium (Ti) and an iron (Fe).

7. The face-down type wafer carrying assembly according to claim 1, wherein based on 100 wt % of a material for manufacturing the high-temperature magnetizable metal plate, the material includes from 40 wt % to less than 100 wt % of a cobalt (Co), 3 to 7 wt % of an aluminium (Al), 8 to 12 wt % of a nickel (Ni), less than 6 wt % of a copper (Cu), less than 1 wt % of a titanium (Ti), and a remaining percentage by weight of an iron (Fe).

8. The face-down type wafer carrying assembly according to claim 1, wherein the magnetizable module includes at least one high-temperature adhesive layer disposed on the high-temperature magnetizable metal plate, and the at least one high-temperature adhesive layer faces downwardly; wherein the at least one high-temperature adhesive layer has an operating temperature less than 2000° C., the at least one high-temperature adhesive layer has an adhesive bottom surface facing downwardly, and at least one wafer is temporarily adhered to the adhesive bottom surface of the at least one high-temperature adhesive layer.

9. A wafer coating device using a face-down type wafer carrying assembly, wherein the face-down type wafer carrying assembly comprises:
a magnetic force generating module;
a temperature control module adjacent to the magnetic force generating module; and
a magnetizable module disposed on the temperature control module;
wherein the magnetizable module includes a high-temperature magnetizable metal plate disposed on the temperature control module.

10. A wafer coating device comprising a top chamber structure and a bottom chamber structure mated with the top chamber structure, the wafer coating device using a face-down type wafer carrying assembly that is disposed on the top chamber structure, wherein the face-down type wafer carrying assembly comprises:
a magnetic force generating module;
a temperature control module adjacent to the magnetic force generating module; and
a magnetizable module disposed on the temperature control module;
wherein the magnetizable module includes a high-temperature magnetizable metal plate disposed on the temperature control module.
